(19) United States
(12) Patent Application Publication
(10) Pub. No.: US 2021/0319726 A1
(43) Pub. Date: Oct. 14, 2021

(54) STRETCHABLE DISPLAY PANEL, PREPARATION METHOD THEREOF, AND STRETCHABLE ELECTRONIC DEVICE

(71) Applicant: Shenzhen Royole Technologies Co., Ltd., Shenzhen (CN)

(72) Inventors: Jiahao Kang, Shenzhen (CN); Jigang Zhao, Shenzhen (CN); Yu-Min Wang, Shenzhen (CN); Wenbing Hu, Shenzhen (CN); Haojun Luo, Shenzhen (CN); Ze Yuan, Shenzhen (CN)

(21) Appl. No.: 17/225,312

(22) Filed: Apr. 8, 2021

(30) Foreign Application Priority Data
Apr. 8, 2020 (CN) 202010277723.1

(51) Int. Cl. G09F 9/30

(52) U.S. Cl. CPC G09F 9/301; G06F 1/1652

(57) ABSTRACT

The method includes providing a rigid base plate; forming an etch-stop layer on one side of the rigid base plate; forming a first flexible substrate on another side of the etch-stop layer; fabricating a plurality of stretchable circuits on the surface of the first flexible substrate facing away from the etch-stop layer; etching a first flexible substrate between two adjacent stretchable circuits to form a through hole; forming a first elastic layer that covers the plurality of stretchable circuits and fills the through hole; separating the rigid base plate and the etch-stop layer; and forming a second elastic layer opposite to the first elastic layer such that the plurality of stretchable circuits is encircled by the first and second elastic layers.

### TECHNICAL FIELD

The application relates to the display technical field, in particular to a method for preparing stretchable display panel, a stretchable panel, and a stretchable electronic device.

### BACKGROUND

With the development of technology, consumers demand more and more diverse electronic products. Stretchable electronic devices are favored by consumers because they have stretchable properties that differ from other conventional electronic devices. Stretchable display panels are important parts of stretchable electronic devices. The quality of the stretchable display panel is directly related to the quality of the stretchable electronic device. However, for various reasons, the yield is not high when the stretchable display panel is prepared.

### SUMMARY

The first aspect of the application provides a method for preparing a stretchable panel, including: providing a rigid base plate; forming an etch-stop layer on one side of the rigid base plate; forming a first flexible substrate on a surface of the etch-stop layer facing away from the rigid base plate; fabricating a plurality of stretchable circuits on a surface of the first flexible substrate facing away from the etch-stop layer; etching the first flexible substrate located between two adjacent stretchable circuits and penetrating through two surfaces of the first flexible substrate respectively adjacent to and facing away from the rigid base plate thereby forming a through hole; forming a first elastic layer that covers the plurality of stretchable circuits and fills the through hole; separating the rigid base plate and the etch-stop layer; and forming a second elastic layer opposite to the first elastic layer, the first and second elastic layers cooperatively encircling the plurality of stretchable circuits.

The second aspect of the application provides a stretchable panel, including: a first elastic layer arranged with a plurality of grooves arranged at intervals; a plurality of stretchable circuits arranged in the grooves; a plurality of flexible sections arranged in the grooves, wherein the flexible sections are arranged facing away from a groove bottom of the grooves compared with the stretchable circuits, and the flexible sections protrude out of a periphery of the stretchable circuits; and a second elastic layer, the first and second elastic layers cooperatively encircling the plurality of stretchable circuits and the plurality of flexible sections, wherein a surface of a part where the second elastic layer is connected with the plurality of flexible sections is a plane.

The third aspect of the application also provides a stretchable electronic device including the stretchable panel of the second aspect.

According to the application, the etch-stop layer is formed on one side of the rigid base plate. When the first flexible substrate is etched, the etching depth of the first flexible substrate is controllable due to the existence of the etch-stop layer, so that the yield of the prepared stretchable panel is favorably improved.

### BRIEF DESCRIPTION OF THE DRAWINGS

FIG. 1 is a flow diagram of a method for preparing a stretchable panel provided in an embodiment of the present application.

FIG. 2 is a flow diagram of a specific method for preparing a stretchable panel provided in an embodiment of the present application.

FIGS. 3-14 are schematic structural diagrams corresponding to a preparing method for a stretchable panel provided by an embodiment of the present application.

FIG. 15 is a flow diagram of a specific method for preparing a stretchable panel provided by another embodiment of the present application.

FIGS. 16-26 are schematic structural diagrams corresponding to a preparation method for preparing a panel provided by another embodiment of the present application.

FIG. 27 is a flow diagram of a specific method for preparing a stretchable panel provided by yet another embodiment of the present application.

FIGS. 28-37 are schematic structural diagrams corresponding to a method for preparing a stretchable panel provided by a further embodiment of the present application.

FIG. 38 is a schematic structural diagram of a stretchable panel provided by an embodiment of the present application.

FIG. 39 is a schematic structural diagram of a stretchable panel provided by another embodiment of the present application.

FIG. 40 is a schematic structural diagram of a stretchable panel provided by a further embodiment of the present application.

FIG. 41 is a schematic diagram of a stretchable electronic device provided by an embodiment of the present application.

### DETAILED DESCRIPTION

The following will clearly and completely describe the technical solutions in the embodiments of the present application in conjunction with the drawings in the embodiments of the present application. Obviously, the described embodiments are only part of the embodiments of the present application, rather than all the embodiments. Based on the embodiments of the present application, all other embodiments obtained by one of ordinary skills in the art without involving any inventive efforts are within the scope of the present application.

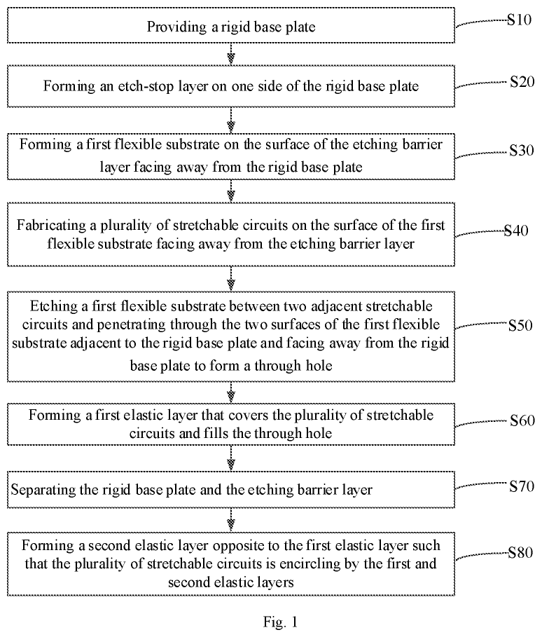

Referring to FIG. 1, there is provided a flow diagram of a method for preparing a stretchable panel provided in an embodiment of the present application. The method for preparing a stretchable panel includes, but is not limited to, S10, S20, S30, S40, S50, S60, S70, and S80; S10, S20, S30, S40, S50, S60, S70, and S80 are described below.

S10, providing a rigid base plate.

S20, forming an etch-stop layer on one side of the rigid base plate.

S30, forming a first flexible substrate on the surface of the etch-stop layer facing away from the rigid base plate.

S40, fabricating a plurality of stretchable circuits on the surface of the first flexible substrate facing away from the etch-stop layer.

S50, etching a first flexible substrate between two adjacent stretchable circuits and penetrating through the two surfaces of the first flexible substrate adjacent to the rigid base plate and facing away from the rigid base plate to form a through hole.

S60, forming a first elastic layer that covers the plurality of stretchable circuits and fills the through hole.

S70, separating the rigid base plate and the etch-stop layer.

S80, forming a second elastic layer opposite to the first elastic layer to clamp the plurality of stretchable circuits in cooperation with the first elastic layer.

According to the application, the etch-stop layer is formed on one side of the rigid base plate. When the first flexible substrate is etched, the etching depth of the first flexible substrate is controllable due to the existence of the etch-stop layer, so that the yield of the prepared stretchable panel is favorably improved.

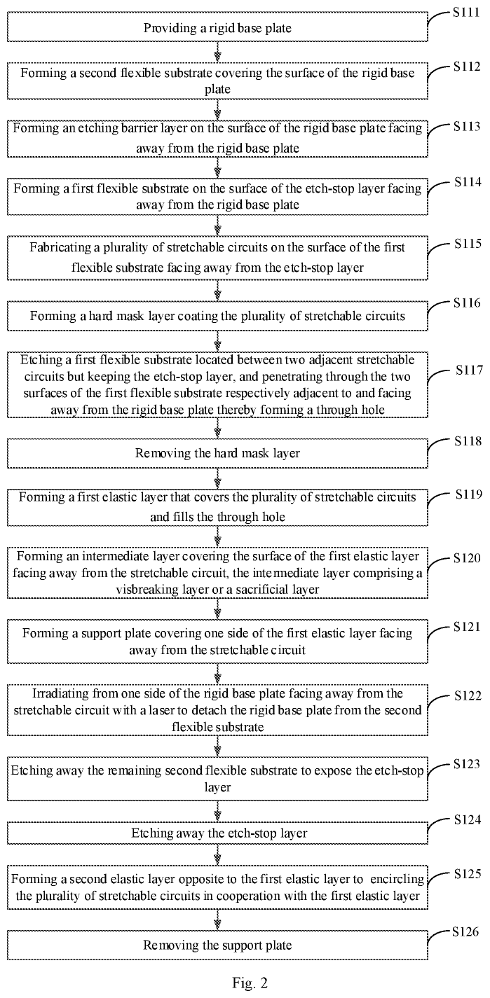

The preparation method for the above-mentioned stretchable panel 10 will be described in detail below in conjunction with the drawings, and please refer to FIG. 2. FIG. 2 is a flow diagram of a specific method for preparing a stretchable panel provided in an embodiment of the present application.

S111, providing a rigid base plate 110.

The rigid base plate 110 may be made of, but is not limited to, glass and the like.

S112, forming a second flexible substrate 100 covering the surface of the rigid base plate 110;

The material of the second flexible substrate 100 can be, but is not limited to, a polyimide (PI) thin film, and the thickness of the second flexible substrate 100 can be, but is not limited to: 5 μm˜15 μm. The PI thin film is generally yellow transparent, has a relative density of 1.39-1.45, has excellent high and low temperature resistance, electrical insulation, adhesion, radiation resistance, chemical resistance, and the like, and can be used for a long time in the temperature range of −269° C.˜280° C. The PI thin film is also currently preferred flexible substrates with the excellent mechanical property.

S113, forming an etch-stop layer 120 on the surface of the rigid base plate 110 facing away from the rigid base plate 110;

By etch-stop layer 120, it is meant that certain etching solutions may be blocked during the etching process to prevent the etching solutions from damaging parts or film layers (e.g., second flexible substrate 100 herein) covered by the etch-stop layer 120.

S114, forming a first flexible substrate on the surface of the etch-stop layer 120 facing away from the rigid base plate 110.

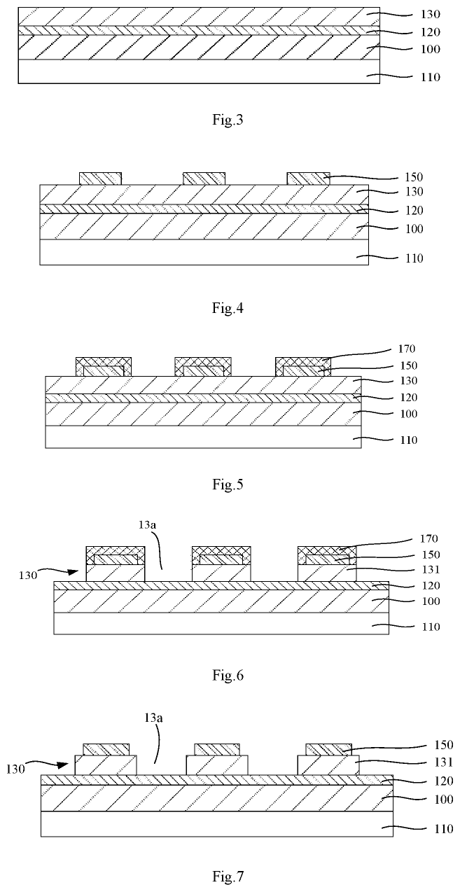

The first flexible substrate 130 may be, but is not limited to, PI film. The materials of the first flexible substrate 130 and the second flexible substrate 100 may or may not be the same. The structure diagram of the stretchable panel 10 corresponding to S111˜S114 is shown in FIG. 3.

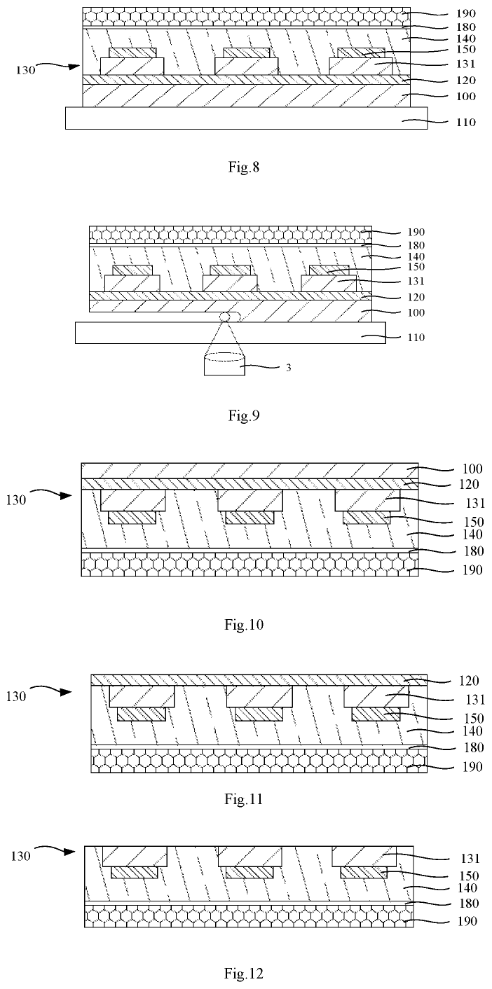

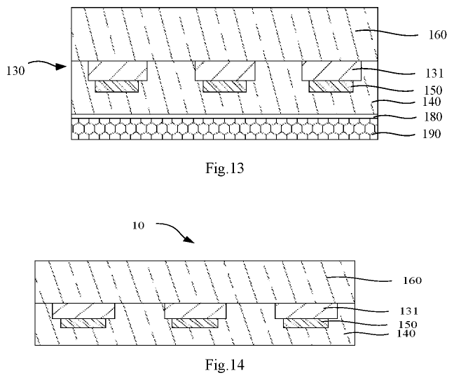

S115, fabricating a plurality of stretchable circuits 150 on the surface of the first flexible substrate 130 facing away from the etch-stop layer 120; referring to FIG. 4.

The plurality of stretchable circuits 150 are circuits that can perform corresponding functions, for example, the stretchable circuits 150 may include a light emitting diode and a driving circuit that drives the light emitting diode to emit light, etc. In other embodiments, the stretchable circuit 150 may also include rigid electronic components and stretchable leads connected between the rigid electronic components.

S116 forming a hard mask layer 170 coating the plurality of stretchable circuits 150. See FIG. 5.

The hard mask layer 170 (Hard Mask) is used to protect the stretchable circuit 150 from damage during the subsequent etching process. The hard mask layer 170 surrounds the surface of the stretchable circuit 150 facing away from the first flexible substrate 130 and each side of the stretchable circuit 150. The material of the hard mask is usually an inorganic thin film material, for example, its main constituents usually include TiN, SiN, SiO2, etc.

S117, etching a first flexible substrate 130 between two adjacent stretchable circuits 150 but keeping the etch-stop layer 120, and penetrating through the two surfaces of the first flexible substrate 130 adjacent to the rigid base plate 110 and facing away from the rigid base plate 110 to form a through hole 13a; referring to FIG. 6.

When the etching solution etches the first flexible substrate 130, the etching solution for etching the first flexible substrate 130 does not damage the hard mask layer 170, so that in the etching process herein, since the stretchable circuit 150 is covered by the hard mask layer 170, the etching solution does not damage the stretchable circuit 150 as well. The portion of the first flexible substrate 130 not covered by the hard mask layer 170 is etched by the etching solution and the etching penetrates to the surface of the first flexible substrate 130 adjacent to the rigid base plate 110. In other words, the first flexible substrate 130 forms a plurality of flexible sections 131 arranged at intervals.

S118, removing the hard mask layer 170. See FIG. 7.

The hard mask layer 170 may be removed by, not limited to, stripping (Strip). After the hard mask layer 170 is removed, the stretchable circuit 150 on the flexible section 131 is exposed. Each stretchable circuit 150 is located on the flexible section 131, and the flexible section 131 protrudes from the peripheral side of the stretchable circuit 150.

S119, forming a first elastic layer 140 that covers the plurality of stretchable circuits and fills the through hole 13a;

The material of the first elastic layer 140 may be a PI material, or Polydimethylsiloxane (PDMS).

S120, forming an intermediate layer 180 covering the surface of the first elastic layer 140 facing away from the stretchable circuit 150. The intermediate layer 180 comprises a visbreaking layer or a sacrificial layer.

The arrangement of the intermediate layer 180 may facilitate the separation of the support plate 190 from the first elastic layer 140, and it will be appreciated that in other embodiments, the intermediate layer 180 may not be arranged.

S121, forming a support plate 190 covering one side of the first elastic layer 140 facing away from the stretchable circuit 150. Figures corresponding to S119˜S121 refer to FIG. 8.

The support plate 190 is arranged to support film layers and parts such as the first elastic layer 140 in the subsequent process (e.g., laser irradiation process).

S122 irradiating from one side of the rigid base plate 110 facing away from the stretchable circuit 150 with a laser to detach the rigid base plate 110 from the second flexible substrate 100; referring to FIGS. 9 and 10.

The laser emitted by the laser apparatus 3 is irradiated from one side of the rigid base plate 110 facing away from the stretchable circuit 150 such that the portion of the second flexible substrate 100 adjacent to the rigid base plate 110 is irradiated by the laser without being bonded to the rigid base plate 110.

S123, etching away the remaining second flexible substrate 100 to expose the etch-stop layer 120. See FIG. 11.

In the S122 process, by irradiating laser from one side of the rigid base plate 110 facing away from the stretchable circuit 150, a portion of the second flexible substrate 100 is removed and a portion of the second flexible substrate 100 remains. The remaining second flexible substrate 100 is removed in the process. The etching solution that etches the second flexible substrate 100 can only etch away the remaining second flexible substrate 100 without damaging the etch-stop layer 120.

S124, etching away the etch-stop layer 120; referring to FIG. 12.

The etching liquid that etches away the second flexible substrate 100 does not damage the etch-stop layer 120, and accordingly, the etching liquid that etches the etch-stop layer 120 does not damage the first flexible substrate 130 or the second flexible substrate 100.

S125 forming a second elastic layer 160 opposite to the first elastic layer 140 to clamp the plurality of stretchable circuits 150 in cooperation with the first elastic layer 140. See FIG. 13.

S126 removing the support plate 190. Removing the support plate 190 is that the support plate 190 is separated from the first elastic layer 140. See FIG. 14.

When there is an intermediate layer 180 between the support plate 190 and the first elastic layer 140, it is also required to remove the intermediate layer 180.

When there is an intermediate layer 180 between the support plate 190 and the first elastic layer 140, the method for separating the support plate 190 from the first elastic layer 140 comprises the following steps: separating the support plate 190 from the first elastic layer 140 in a mechanical stripping manner; alternatively, when the intermediate layer 180 comprises a sacrificial layer, dissolving the sacrificial layer by a chemical approach to separate the support plate 190 from the first elastic layer 140.

According to the application, the rigid base plate 110 is separated from the second flexible substrate 100 by irradiating laser from one side of the rigid base plate 110 facing away from the stretchable circuit 150. Then the second flexible substrate 100 is etched, and the etch-stop layer 120 is etched so that the roughness of a plurality of flexible sections 131 (also referred to as flexible island) formed by the remaining first flexible substrate 130 is controllable, and the transparency of the finally prepared stretchable panel 10 is comparatively good.

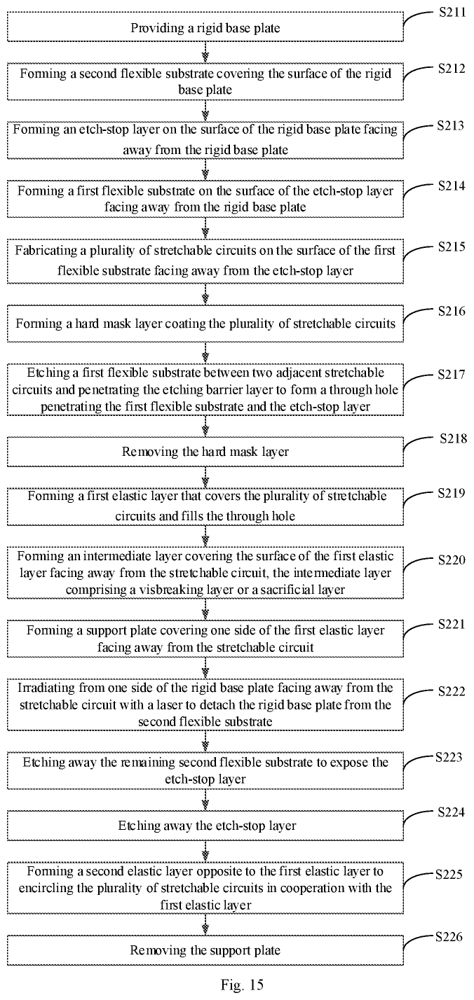

The preparation method for the above-mentioned stretchable panel 10 will be described in detail below. Please refer to FIG. 15. FIG. 15 is a flow diagram of a specific method for preparing a stretchable panel provided by another embodiment of the present application. Regarding the same terms or processes and the like appearing in the present embodiment as those in the foregoing embodiments, reference is made to the foregoing description and a detailed description thereof will not be repeated in the present embodiment.

S211, providing a rigid base plate 110.

S212, forming a second flexible substrate 100 covering the surface of the rigid base plate 110.

S213, forming an etch-stop layer 120 on the surface of the rigid base plate 110 facing away from the rigid base plate 110;

S214, forming a first flexible substrate 130 on the surface of the etch-stop layer 120 facing away from the rigid base plate 110.

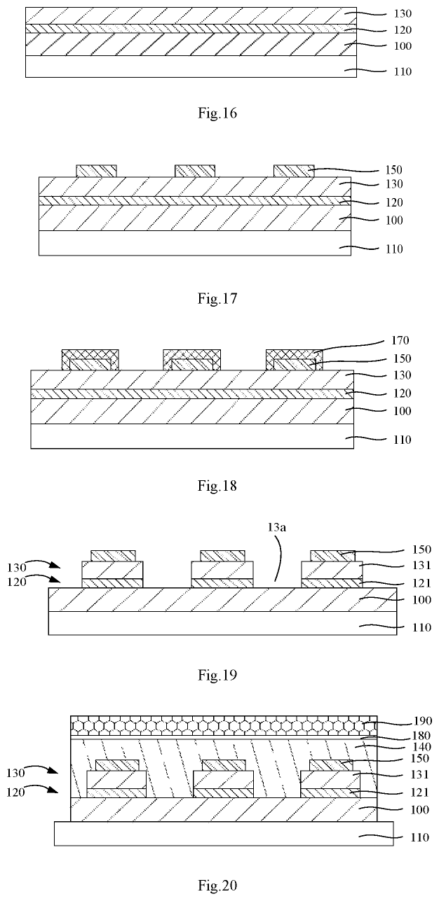

Reference is made to FIG. 16 for a corresponding structural diagram of S211-S214.

S215, fabricating a plurality of stretchable circuits 150 on the surface of the first flexible substrate 130 facing away from the etch-stop layer 120; referring to FIG. 17

S216, forming a hard mask layer 170 coating the plurality of stretchable circuits 150; referring to FIG. 18

S217, etching a first flexible substrate 130 between two adjacent stretchable circuits 150 and penetrating the etch-stop layer 120 to form a through hole 13a penetrating the first flexible substrate 130 and the etch-stop layer 120.

In the process, since both the first flexible substrate 130 and the etch-stop layer 120 are etched, the first flexible substrate 130 forms a plurality of flexible sections 131 arranged at intervals, and the etch-stop layer 120 forms a plurality of etch-stop sections 121 arranged at intervals. The etch-stop section 121 is in one-to-one correspondence with the flexible section

131. Specifically, one flexible section 131 is arranged on one etch-stop section 121, and a different flexible section 131 is arranged on a different etch-stop section 121.

S218, removing the hard mask layer 170. For S217˜S218, please refer to FIG. 19.

S219, forming a first elastic layer 140 that covers the plurality of stretchable circuits and fills the through hole.

S220, forming an intermediate layer 180 covering the surface of the first elastic layer 140 facing away from the stretchable circuit 150. The intermediate layer 180 comprises a visbreaking layer or a sacrificial layer. The intermediate layer 180 is arranged to facilitate the separation of the support plate 190 from the first elastic layer 140.

S221, forming a support plate 190 covering one side of the first elastic layer 140 facing away from the stretchable circuit 150; S219˜S221 referring to FIG. 20.

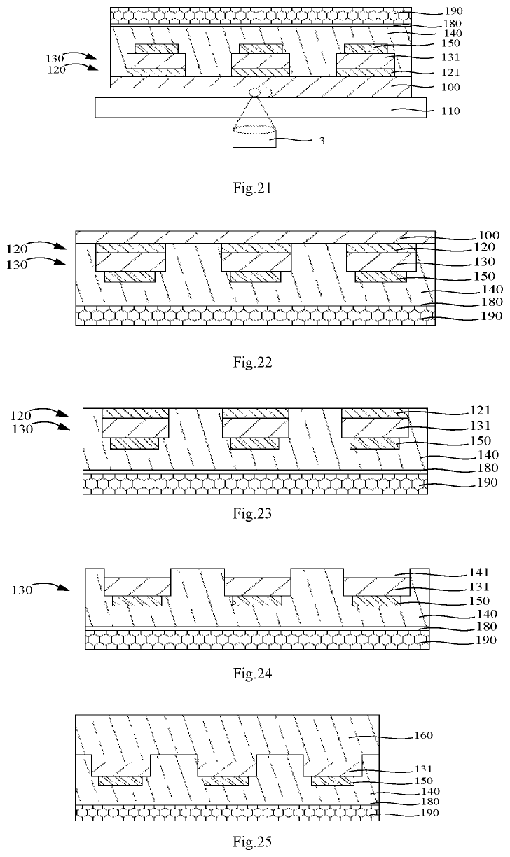

S222 irradiating from one side of the rigid base plate 110 facing away from the stretchable circuit 150 with a laser to detach the rigid base plate 110 from the second flexible substrate 100. The laser comes from laser apparatus 3, referring to FIGS. 21 and 22.

S223, etching away the remaining second flexible substrate 100 to expose the etch-stop layer 120; referring to FIG. 23.

Since the etch-stop layer 120 is etched in S217, the remaining etch-stop layer 120 is exposed in the present process, that is, the plurality of etch-stop sections 121 is exposed.

S224, etching away the etch-stop layer 120.

The etching liquid that etches away the second flexible substrate 100 does not damage the etch-stop layer 120, and accordingly, the etching solution that etches the etch-stop layer 120 does not damage the first flexible substrate 130 or the second flexible substrate 100. According to the application, the rigid base plate 110 is separated from the second flexible substrate 100 by irradiating laser from one side of the rigid base plate 110 facing away from the stretchable circuit 150. Then the second flexible substrate 100 is etched, and the etch-stop layer 120 is etched so that the roughness of the flexible section 131 formed by the remaining first flexible substrate 130 is controllable, and the transparency is comparatively good.

Since the etch-stop layer 120 is etched in S217, the remaining etch-stop layer 120 is etched away in the present process, that is, the plurality of etch-stop sections 121 is etched away. Since the etch-stop section 121 is etched away, a groove 141 is formed on the surface of the first elastic layer 140 facing away from the support plate 190. See FIG. 24.

S225, forming a second elastic layer 160 opposite to the first elastic layer 140 to clamp the plurality of stretchable circuits 150 in cooperation with the first elastic layer 140.

The second elastic layer 160 fills at least the groove 141. See FIG. 25.

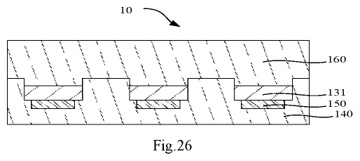

S226, removing the support plate 190. Removing the support plate 190 is that the support plate 190 is separated from the first elastic layer 140. See FIG. 26.

When there is an intermediate layer 180 between the support plate 190 and the first elastic layer 140, the method for separating the support plate 190 from the first elastic layer 140 comprises the following steps: separating the support plate 190 from the first elastic layer 140 in a mechanical stripping manner; alternatively, when the intermediate layer 180 comprises a sacrificial layer, dissolving the sacrificial layer by a chemical approach to separate the support plate 190 from the first elastic layer 140.

It will be appreciated that in other embodiments, S220 is also included between S219 and S221. S220 is described in detail as below.

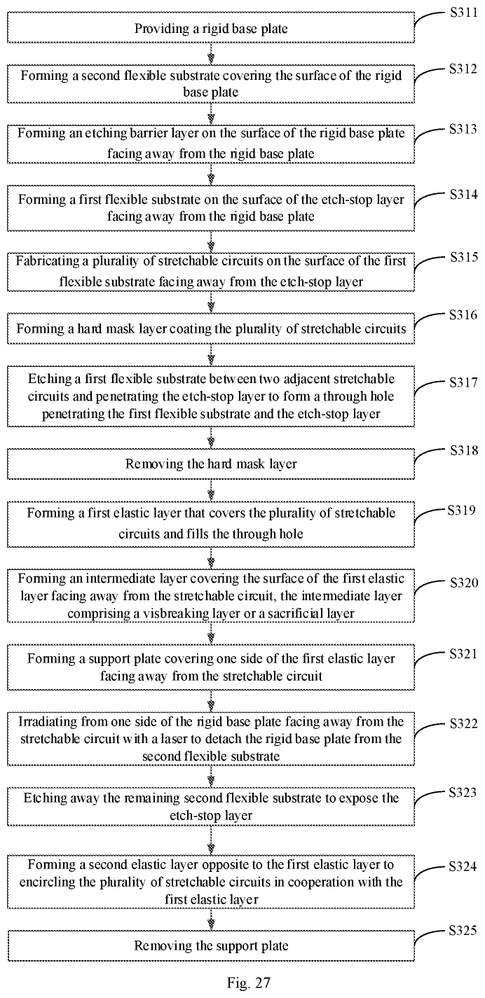

The preparation method for the above-mentioned stretchable panel 10 will be described in detail below, and please refer to FIG. 27. FIG. 27 is a flow diagram of a specific method for preparing a stretchable panel provided by yet another embodiment of the present application. Regarding the same terms or processes and the like appearing in the present embodiment as those in the foregoing embodiments, reference is made to the foregoing description and a detailed description thereof will not be repeated in the present embodiment.

S311, providing a rigid base plate 110.

S312, forming a second flexible substrate 100 covering the surface of the rigid base plate 110.

S313, forming an etch-stop layer 120 on the surface of the rigid base plate 110 facing away from the rigid base plate 110.

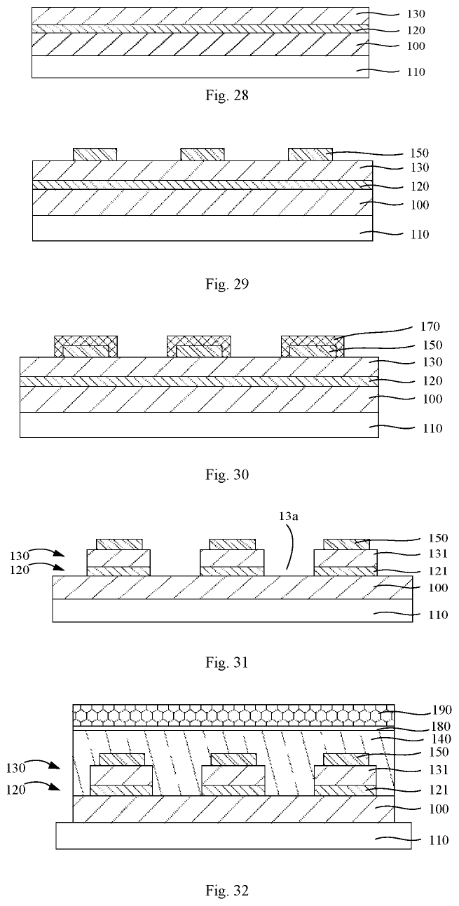

S314, forming a first flexible substrate 130 on the surface of the etch-stop layer 120 facing away from the rigid base plate 110; referring to FIG. 28 for a corresponding schematic structural diagram of S311-S314.

S315, fabricating a plurality of stretchable circuits 150 on the surface of the first flexible substrate 130 facing away from the etch-stop layer 120; referring to FIG. 29.

S316, forming a hard mask layer 170 coating the plurality of stretchable circuits 150; referring to FIG. 30.

S317, etching a first flexible substrate 130 between two adjacent stretchable circuits 150 and penetrating the etch-stop layer 120 to form a through hole 13a penetrating the first flexible substrate 130 and the etch-stop layer 120; referring to FIG. 31.

In the process, since both the first flexible substrate 130 and the etch-stop layer 120 are etched, the first flexible substrate 130 forms a plurality of flexible sections 131 arranged at intervals, and the etch-stop layer 120 forms a plurality of etch-stop sections 121 arranged at intervals. The etch-stop section 121 is in one-to-one correspondence with the flexible section 131. Specifically, one flexible section 131 is arranged on one etch-stop section 121, and a different flexible section 131 is arranged on a different etch-stop section 121.

S318, removing the hard mask layer 170.

S319, forming a first elastic layer 140 that covers the plurality of stretchable circuits and fills the through hole.

S320, forming an intermediate layer 180 covering the surface of the first elastic layer 140 facing away from the stretchable circuit 150. The intermediate layer 180 comprises a visbreaking layer or a sacrificial layer. The intermediate layer 180 is arranged to facilitate the separation of the support plate 190 from the first elastic layer 140.

S321, forming a support plate 190 covering one side of the first elastic layer 140 facing away from the stretchable circuit 150; S318˜S321 referring to FIG. 32.

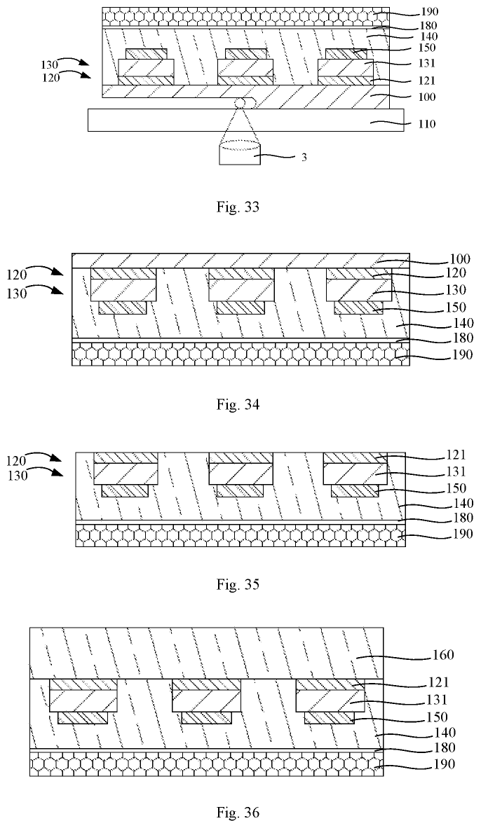

S322 irradiating from one side of the rigid base plate 110 facing away from the stretchable circuit 150 with a laser to detach the rigid base plate 110 from the second flexible substrate 100; the laser coming from a laser apparatus 3, referring to FIGS. 33 and 34.

S323, etching away the remaining second flexible substrate 100 to expose the etch-stop layer 120; referring to FIG. 35.

In the embodiment, since a portion of the etch-stop layer 120 is etched away in S317, the remaining etch-stop layer 120 forms a plurality of etch-stop sections 121 arranged at intervals. The plurality of etch-stop sections 121 is not removed in S323 so that the plurality of etch-stop sections 121 is reserved.

S324, forming a second elastic layer 160 opposite to the first elastic layer 140 to clamp the plurality of stretchable circuits 150 in cooperation with the first elastic layer 140. See FIG. 36.

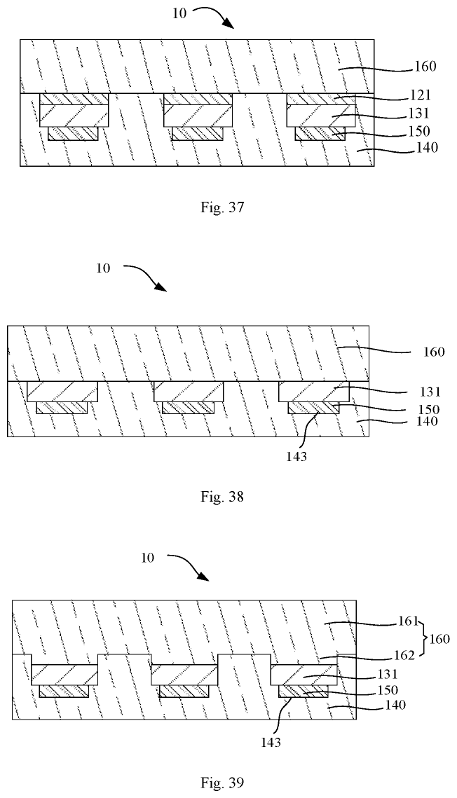

S325, removing the support plate 190. Removing the support plate 190 is that the support plate 190 is separated from the first elastic layer 140. See FIG. 37.

When there is an intermediate layer 180 between the support plate 190 and the first elastic layer 140, the method for separating the support plate 190 from the first elastic layer 140 comprises the following steps: separating the support plate 190 from the first elastic layer 140 in a mechanical stripping manner; alternatively, when the intermediate layer 180 comprises a sacrificial layer, dissolving the sacrificial layer by a chemical approach to separate the support plate 190 from the first elastic layer 140.

The present application also provides a stretchable panel 10. The stretchable panel 10 provided in the present application will be described in detail below in conjunction with the preparation method for the stretchable panel 10 described above. The preparation method for the stretchable panel described above may prepare the stretchable panel described below. Referring to FIG. 38, there is provided a schematic structural diagram of a stretchable panel provided by an embodiment of the present application.

The stretchable panel 10 comprises:

a first elastic layer 140 arranged with a plurality of grooves 143 arranged at intervals;

a plurality of stretchable circuits 150 arranged in the grooves 143;

a plurality of flexible sections 131 arranged in the grooves 143, wherein the flexible

sections 131 are arranged facing away from the groove bottom of the grooves 143 compared with the stretchable circuits 150, and the flexible sections 131 protrude out of the periphery of the stretchable circuits 150; and

a second elastic layer 160 clamping the plurality of stretchable circuits 150 and the plurality of flexible sections 131 in cooperation with the first elastic layer 140, wherein the surface of the part where the second elastic layer 160 is connected with the plurality of flexible sections 131 is a plane.

In the embodiment, the surface of the flexible section 131 facing away from the bottom wall of the groove 143 is flush with the surface of the groove 143 formed by the first elastic layer 140.

The present application also provides a stretchable panel 10. The stretchable panel 10 provided in the present application will be described in detail below in conjunction with the preparation method for the stretchable panel 10 described above. Referring to FIG. 39, there is provided a schematic structural diagram of a stretchable panel provided by another embodiment of the present application. The structure of the stretchable panel 10 provided in the present embodiment is substantially the same as that of the stretchable panel 10 provided in the above-described embodiment and the similarities will not be described in detail. The difference lies in that in the present embodiment, the surface of the groove 143 formed by the first elastic layer 140 protrudes from the surface of the flexible section 131 facing away from the bottom wall of the groove 143; the second elastic layer 160 comprises an elastic body 161 and a plurality of protrusions 162 protruding from the elastic body 161, the protrusions 162 being arranged in the groove 143 to be in contact with the flexible section 131.

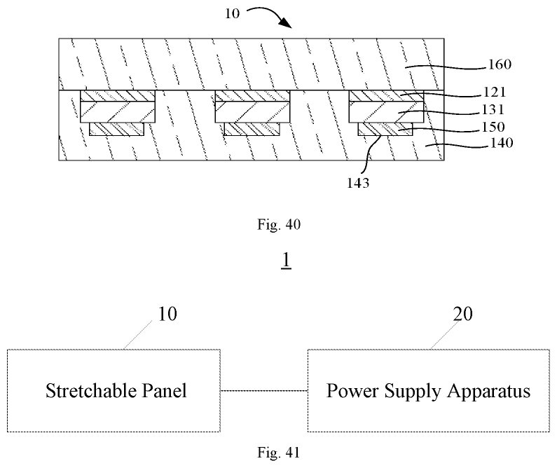

The present application also provides a stretchable panel 10. The stretchable panel 10 provided in the present application will be described in detail below in conjunction with the preparation method for the stretchable panel 10 described above. Referring to FIG. 40, there is provided a schematic structural diagram of a stretchable panel provided by a further embodiment of the present application. The structure of the stretchable panel 10 provided by the embodiment is substantially the same as that of the stretchable panel 10 provided by FIG. 38 and the related embodiments thereof, and the similarities will not be described in detail. The difference lies in that in the present embodiment the stretchable panel 10 further comprises:

a plurality of etch-stop sections 121 arranged in the groove 143, with the etch-stop sections 121 being located on the surface of the flexible section 131 facing away from the stretchable circuit 150.

The present application also provides a stretchable electronic device 1, and please see FIG. 41. FIG. 41 is a schematic diagram of a stretchable electronic device provided by an embodiment of the present application. The stretchable electronic device 1 includes, but is not limited to, stretchable cell phones, electronic books, etc. The stretchable electronic device 1 comprises a stretchable panel 10. The stretchable panel 10 is described with reference to the foregoing description and will not be described in detail herein. The stretchable electronic device 1 may further comprise a power supply apparatus 20 and the like for supplying power to the stretchable panel 10.

The principles and embodiments of the present application have been described in this specification using specific instances. The above examples are only used to help understand the core idea of the present core idea. At the same time, for those of ordinary skills in the art, according to the idea of the application, there will be changes in the specific embodiments and the scope of application. In summary, the content of this specification should not be construed as a limitation of the application.

What is claimed is:

1. A method for preparing a stretchable panel, comprising:
providing a rigid base plate;
forming an etch-stop layer on one side of the rigid base plate;
forming a first flexible substrate on a surface of the etch-stop layer facing away from the rigid base plate;
fabricating a plurality of stretchable circuits on a surface of the first flexible substrate facing away from the etch-stop layer;
etching the first flexible substrate located between two adjacent stretchable circuits and penetrating through two surfaces of the first flexible substrate respectively adjacent to and facing away from the rigid base plate, thereby forming a through hole;
forming a first elastic layer that covers the plurality of stretchable circuits and fills the through hole;
separating the rigid base plate from the etch-stop layer; and
forming a second elastic layer opposite to the first elastic layer, the first and second elastic layers cooperatively encircling the plurality of stretchable circuits.

2. The method for preparing a stretchable panel of claim 1, further comprising: after the step of providing the rigid base plate and before the step of forming the etch-stop layer on one side of the rigid base plate: forming a second flexible substrate covering the surface of the rigid base plate;
wherein the step of forming the etch-stop layer on one side of the rigid base plate comprises: forming the etch-stop layer on the surface of the second flexible substrate facing away from the rigid base plate.

3. The method for preparing a stretchable panel of claim 2, wherein the material of the first flexible substrate or the second flexible substrate is a polyimide thin film.

4. The method for preparing a stretchable panel of claim 2, wherein the thickness of the second flexible substrate is 5 μm˜15 μm.

5. The method for preparing a stretchable panel of claim 2, further comprising: after the step of fabricating a plurality of stretchable circuits on the surface of the flexible substrate facing away from the etch-stop layer: forming a hard mask layer covering the plurality of stretchable circuits;
wherein the step of etching a first flexible substrate located between two adjacent stretchable circuits and penetrating through two surfaces of the first flexible substrate respectively adjacent to and facing away from the rigid base plate, thereby forming a through hole comprises: etching a first flexible substrate between two adjacent stretchable circuits but keeping the etch-stop layer;
wherein the method for preparing a stretchable panel further comprises:
removing the hard mask layer, after the step of etching the first flexible substrate located between two adjacent stretchable circuits and penetrating through two surfaces of the first flexible substrate respectively adjacent to and facing away from the rigid base plate, thereby forming a through hole.

6. The method for preparing a stretchable panel of claim 3, further comprising after the step of forming a first elastic layer that covers the plurality of stretchable circuits and fills the through hole:
forming a support plate covering one side of the first elastic layer facing away from the stretchable circuits;
wherein the method for preparing a stretchable panel further comprises: after the step of forming a first elastic layer that covers the plurality of stretchable circuits and fills the through hole, and before the step of separating the rigid base plate and the etch-stop layer,
irradiating from one side of the rigid base plate facing away from the stretchable circuit with a laser to detach the rigid base plate from the second flexible substrate.

7. The method for preparing a stretchable panel of claim 4, further comprising: after the step of irradiating from one side of the rigid base plate facing away from the stretchable circuit with a laser to detach the rigid base plate
etching away the remaining second flexible substrate to expose the etch-stop layer; and
etching away the etch-stop layer;
wherein the method for preparing a stretchable panel further comprises:
separating the support plate from the first elastic layer, after the step of forming a second elastic layer opposite to the first elastic layer.

8. The method for preparing a stretchable panel of claim 4, wherein the step of forming a support plate covering one side of the first elastic layer facing away from the stretchable circuit comprises:
forming an intermediate layer covering the surface of the first elastic layer facing away from the stretchable circuit, the intermediate layer comprising a visbreaking layer or a sacrificial layer; and
forming the support plate on the surface of the intermediate layer facing away from the first elastic layer;
wherein the method for preparing a stretchable panel further comprises:
separating the support plate from the first elastic layer, after the step of forming a second elastic layer opposite to the first elastic layer.

9. The method for preparing a stretchable panel of claim 6, wherein the step of separating the support plate from the first elastic layer comprises:
separating the support plate from the first elastic layer in a mechanical stripping manner; alternatively, when the intermediate layer comprises a sacrificial layer, dissolving the sacrificial layer by a chemical approach to separate the support plate from the first elastic layer.

10. The method for preparing a stretchable panel of claim 2, further comprising: after the step of fabricating a plurality of stretchable circuits on the surface of the flexible substrate facing away from the etch-stop layer, forming a hard mask layer covering the plurality of stretchable circuits;
wherein the step of etching a first flexible substrate located between two adjacent stretchable circuits and penetrating through two surfaces of the first flexible substrate respectively adjacent to and facing away from the rigid base plate, thereby forming a through hole comprises: etching a first flexible substrate between two adjacent stretchable circuits and penetrating the etch-stop layer;
wherein the method for preparing a stretchable panel further comprises:
removing the hard mask layer after the step of etching a first flexible substrate between two adjacent stretchable circuits and penetrating the etching barrier layer.

11. The method for preparing a stretchable panel of claim 10, further comprising: after the step of forming a first elastic layer that covers the plurality of stretchable circuits and fills the through hole,
forming a support plate covering one side of the first elastic layer facing away from the stretchable circuit;
wherein the method for preparing a stretchable panel further comprises: after the step of forming a first elastic layer that covers the plurality of stretchable circuits and fills the through hole, and before the step of separating the rigid base plate and the etching barrier layer,
irradiating from one side of the rigid base plate facing away from the stretchable circuit with a laser to detach the rigid base plate from the second flexible substrate;
etching away the remaining second flexible substrate to expose the etch-stop layer; and
etching away the etch-stop layer;
wherein the method for preparing a stretchable panel further comprises:
separating the support plate from the first elastic layer after the step of forming a second elastic layer opposite to the first elastic layer.

12. The method for preparing a stretchable panel of claim 10, further comprising: after the step of forming a first elastic layer that covers the plurality of stretchable circuits and fills the through hole,
forming a support plate covering one side of the first elastic layer facing away from the stretchable circuit;
wherein the method for preparing a stretchable panel further comprises: after the step of forming a first elastic layer that covers the plurality of stretchable circuits and fills the through hole, and before the step of separating the rigid base plate and the etch-stop layer
irradiating from one side of the rigid base plate facing away from the stretchable circuit with a laser to detach the rigid base plate from the second flexible substrate; and etching away the remaining second flexible substrate to expose the etch-stop layer, and keeping the etch-stop layer;
wherein the method for preparing a stretchable panel further comprises:
separating the support plate from the first elastic layer after the step of forming a second elastic layer opposite to the first elastic layer.

13. A stretchable panel, comprising:
a first elastic layer arranged with a plurality of grooves arranged at intervals;
a plurality of stretchable circuits arranged in the grooves;
a plurality of flexible sections arranged in the grooves, wherein the flexible sections are arranged facing away from a groove bottom of the grooves compared with the stretchable circuits, and the flexible sections protrude out of a periphery of the stretchable circuits; and
a second elastic layer, the first and second elastic layers cooperatively encircling the plurality of stretchable circuits and the plurality of flexible sections, wherein a surface of a part where the second elastic layer is connected with the plurality of flexible sections is a plane.

14. The stretchable panel of claim 13, wherein the surface of the flexible section facing away from a bottom wall of the groove is flush with a surface where the first elastic layer forms the groove.

15. The stretchable panel of claim 13, wherein the surface where the first elastic layer forms the groove protrudes out of the surface of the flexible section facing away from a bottom wall of the groove; the second elastic layer comprises an elastic body and a plurality of protrusions protruding from the elastic body, wherein the protrusions are arranged in the grooves and are in contact with the flexible sections.

16. The stretchable panel of claim 13, wherein the stretchable panel further comprises:
a plurality of etch-stop sections arranged in the groove, with the etch-stop sections being located on the surface of the flexible section facing away from the stretchable circuit.

17. A stretchable electronic device, comprising a stretchable panel, wherein the stretchable panel comprises:
a first elastic layer arranged with a plurality of grooves arranged at intervals;
a plurality of stretchable circuits arranged in the grooves;
a plurality of flexible sections arranged in the grooves, wherein the flexible sections are arranged facing away from a groove bottom of the grooves compared with the stretchable circuits, and the flexible sections protrude out of a periphery of the stretchable circuits; and
a second elastic layer, the first and second elastic layers cooperatively encircling the plurality of stretchable circuits and the plurality of flexible sections, wherein a surface of a part where the second elastic layer is connected with the plurality of flexible sections is a plane.

18. The stretchable electronic device of claim 18, wherein the surface of the flexible section facing away from a bottom wall of the groove is flush with a surface where the first elastic layer forms the groove.

19. The stretchable electronic device of claim 18, wherein the surface where the first elastic layer forms the groove protrudes out of the surface of the flexible section facing away from the bottom wall of the groove; the second elastic layer comprises an elastic body and a plurality of protrusions protruding from the elastic body, wherein the protrusions are arranged in the grooves and are in contact with the flexible sections.

20. The stretchable electronic device of claim 18, wherein the stretchable panel further comprises:
a plurality of etch-stop sections arranged in the groove, with the etch-stop sections being located on the surface of the flexible section facing away from the stretchable circuit.
